(19) United States
(12) Patent Application Publication
(10) Pub. No.: US 2002/0050605 A1
(43) Pub. Date: May 2, 2002

(54) Method to reduce contact distortion in devices having silicide contacts

(76) Inventor: J.S. Jason Jenq, Pingtung (TW)

Correspondence Address: Steven M. Rabin, RABIN & BERDO, P.C., Suite 500, 1101 14th Street, Washington, DC, 20005, US

(21) Appl. No.: 09/984,868

(22) Filed: Oct. 31, 2001

Related U.S. Application Data
(63) Continuation of application No. 08/775,760, filed on Dec. 31, 1996, now abandoned.
(60) Provisional application No. 60/024,613, filed on Aug. 26, 1996.

(51) Int. Cl. H01L 31/0328

(52) U.S. Cl. 257/200

(57) ABSTRACT

A contact region of doped silicon has a layer of metal silicide on its surface and a layer of a conductive material formed over the surface of the metal silicide, with the thickness and material of the conductive layer chosen so that the conductive layer functions as an antireflection layer during contact via photolithography. This antireflection layer is formed on the surface of a doped silicon contact region by depositing a layer of metal on the doped contact region and annealing to convert the metal layer at least partially to metal silicide. A subsequent anneal converts the metal silicide region into a lower resistivity phase. A third anneal, preferably conducted as a rapid thermal anneal (RTA) in a nitrogen or ammonia ambient, converts a surface portion of the metal silicide to titanium nitride. The third anneal forms a titanium nitride layer of a thickness appropriate to function as an antireflection layer for the wavelength of light used in the lithography of the contact via. The thickness of the titanium nitride layer is made equal to one quarter of the wavelength of the light used to expose the photoresist layer in the via formation process, adjusted to account for the index of refraction of the material used for the titanium nitride layer.

This application claims priority from provisional application Serial No. 60/024,613, filed Aug. 26, 1996.

### BACKGROUND OF THE INVENTION

1. Field of the Invention

The present invention relates to semiconductor devices incorporating contacts to a layer of metal silicide formed over a silicon region and, more particularly, to the formation of such contacts.

2. Description of the Related Art

As line widths and geometries for semiconductor devices are made smaller, the polysilicon electrodes that form the gates of MOS devices and wiring lines within semiconductor devices become undesirably resistive. Multilayer electrodes in which a layer of polysilicon is covered by one or more layers of metals or metal silicides are used to provide electrodes having a lower resistance than electrodes consisting solely of polysilicon. Silicide electrodes may consist, for example, of a layer of polysilicon having a thickness of approximately 1000 Å to 3000 Å covered by titanium silicide having a thickness of at least 100 Å. Frequently, silicided contact regions are also formed in devices having multilayer wiring lines because silicided contact regions provide more ohmic and lower resistance contacts.

A typical implementation of a MOS device incorporating multilayer electrodes and silicided contacts is the so-called self-aligned silicide (“salicide”) structure, schematically illustrated in FIGS. 1-4. FIGS. 1-4 show cross-sectional views of a MOS transistor at an early stage of manufacture. The illustrated MOS transistor is formed on a P-type substrate 10 and includes thick field oxide regions 12 to provide isolation from other, adjacent MOS devices. A gate oxide layer 14 is formed by thermal oxidation to cover the active device region of the device and a polysilicon gate electrode 16 is formed on the gate oxide layer 14. The polysilicon gate electrode 16 is formed by depositing a layer of undoped polysilicon over the substrate, typically using low pressure chemical vapor deposition (LPCVD), implanting and activating impurities in the polysilicon to render it conductive, and patterning the polysilicon using photolithography. Polysilicon wiring line 18 is formed on the field oxide region 12 at the same time as the gate electrode 16.

Doped source/drain regions 20, 21 are formed on either side of the polysilicon gate electrode and define the channel region of the illustrated MOS transistor. Often, a lightly doped drain (LDD) structure is used in small design rule MOS transistors of the type that are primarily used in modern memory and logic devices. LDD source/drain regions 20, 21 are typically formed in a two step process, beginning with a relatively low dosage ion implantation made self-aligned to a polysilicon gate electrode 16 as illustrated in FIG. 1. Subsequently, spacer oxide regions 22 (FIG. 2) are formed on either side of the gate electrode by first depositing a layer of CVD oxide over the FIG. 1 structure and then anisotropically etching back the oxide layer to expose the substrate over the source/drain regions 20, 21. Etching back the CVD oxide layer produces the spacer oxide regions 22 on either side of the polysilicon gate electrode 16. This process also provides spacer regions 24 on either side of the polysilicon wiring line 18, if the wiring line 18 is exposed during the oxide deposition and etch back process. After the spacer oxide regions 22 are provided on either side of the polysilicon gate electrode 16, a second, higher dosage ion implantation is made into the source/drain regions 20 self-aligned to the spacer oxide regions 22 (not shown).

To reduce the resistance of the FIG. 2 polysilicon gate electrode 16, wiring line 18, and the source/drain regions 20, 21, processing of the FIG. 2 device continues to convert gate electrode 16, wiring line 18 and source/drain regions 20, 21 into layered metal silicide on silicon structures using self-aligned silicide (salicide) techniques. Although a variety of different silicides are known to be acceptable, the silicide most commonly used at this time is titanium silicide, and that structure is described herein. Referring now to FIG. 3, metal silicide on silicon layers are formed by first sputtering a layer of titanium over the surface of the device to a thickness of, for example, 500 Å. This titanium layer 26 is converted into titanium silicide at the surface of the polysilicon layers 16, 18 and at the exposed portions of the substrate, including the source/drain regions 20, 21 in a series of process steps. First, the device is subjected to a rapid thermal anneal (RTA) by heating the device to a temperature of up to about 700° C. for about thirty seconds, converting the titanium layer 26 into titanium silicide (nominally TiSi₂) where the titanium layer is in contact with a silicon (crystalline or polycrystalline) surface. The device is then selectively etched using a wet etch consisting of H₂O₂ and NH₄OH diluted in water, removing unreacted titanium from the surface of the device and exposing the oxide spacer and field isolation regions of the device. Layers of titanium silicide 30, 32 are left over the polysilicon gate electrode 16 and over the wiring line 18. Titanium silicide regions 34, 35 are also formed on the surface of the source/drain regions 20, 21. Such titanium silicide regions 34, 35 provide lower sheet resistance over the source/drain regions and provide better, more ohmic contacts to the source/drain regions 20, 21. Silicided contacts on the source/drain regions are typically preferred so long as the amount of silicon consumed in the silicidation process does not alter the device performance or result in excessive junction leakage at the source/drain regions.

After the unreacted titanium is etched from the device, further processing is necessary to provide suitable self-aligned suicide (salicide) structures for the gate electrodes, wiring lines and source/drain (or other contact regions) of the device. The process steps described to this point form a relatively high resistivity phase (C49) of titanium silicide on the silicon surfaces, so that the illustrated salicide structure does not have as low of resistivity as is desirable. It is accordingly necessary to expose the device to a second rapid thermal anneal at a temperature in excess of 800° C. for at least ten seconds to convert the titanium silicide to the lower resistivity phase (C54) of titanium silicide.

The device is then subjected to further processing to complete the device. For example, if the illustrated device includes a memory cell of a dynamic random access memory device, a charge storage capacitor structure might be formed connected to one of the source/drain regions, for example, source/drain region 21. In such a case, a bit line contact would be formed in contact with the other of the source/drain regions 20. FIG. 5 schematically illustrates this process. A layer of silicon oxide 36 is formed over the FIG. 4 by, for example, depositing one or more layers of oxide using chemical vapor deposition (CVD) with a tetra-ethyl-ortho-silicate (TEOS) source. A layer of photoresist is provided on the layer of oxide 36 and the photoresist is exposed by projecting light through a mask to alter regions of the photoresist to convert them into a form that is, for example, easily removed with unexposed photoresist remaining in place. The exposed portion of the photoresist layer is removed to expose a portion of the surface of the oxide layer 36 above the source/drain region 20. Reactive ion etching (RIE) using a fluorine-etch chemistry is performed to provide a via 38 to the titanium silicide layer 34 at the surface of the source/drain region 20. Metallization is then deposited to fill the via 38, making contact to the source/drain region 20.

The FIG. 5 via formation process is, however, idealized. Referring to FIG. 6, the photoresist layer 40 is exposed by passing light through an exposure mask so that a light pattern is incident on the surface of the photoresist layer. Light 42 passing through the photoresist layer 40 exposes the photoresist layer, but may also pass into the oxide layer and be reflected from the often uneven surface of the titanium silicide layer 34. Reflections from the titanium silicide layer 34 are particularly strong for deep ultraviolet (DUV) lithography at, for example, λ=245 or 198 nm. Light 42 passing through the photoresist on a first pass exposes regions of photoresist having sharp, vertical edges. The spurious reflections from the surface of the titanium silicide layer 34, however, can expose unwanted regions of the photoresist. When the exposed portions of the photoresist 40 are removed, the resulting via may have distorted edges 46. Subsequent etching then forms a distorted via through the oxide layer 36. Such a distorted contact via can cause device failures and prevent the contact via from being formed close to other structures in the semiconductor device.

### SUMMARY OF THE PREFERRED EMBODIMENTS

It is accordingly an object of the present invention to provide a silicided contact structure which is more compatible with the formation of undistorted contact structures.

One aspect of the present invention provides a method of making a semiconductor device, which includes the steps of providing a semiconductor substrate and doping a contact region to render the contact region conductive. A layer of metal is deposited over the semiconductor device and on the contact region and a first anneal of the semiconductor device is performed to produce a layer of metal silicide on the contact region. Unreacted portions of the layer of metal are removed from the semiconductor device. Subsequently, a rapid thermal anneal of the semiconductor device is performed in a nitrogen ambient at a temperature sufficient to cause the nitrogen ambient to react with the layer of metal silicide on the contact region, causing a layer of metal nitride to grow on the layer of metal silicide. A layer of insulating material is then provided over the semiconductor device and photolithography is used to define a via through the layer of insulating material to expose the layer of metal nitride.

Another aspect of the invention provides a method of making a semiconductor device in which a semiconductor substrate is provided and a contact region is doped to render the contact region conductive. A layer of metal is deposited over the semiconductor device and on the contact region and a first anneal of the semiconductor device is performed to produce a layer of metal silicide on the contact region. Unreacted portions of the layer of metal are removed from the semiconductor device. Rapid thermal annealing of the semiconductor device is performed in an annealing ambient to form a conductive antireflection layer on the layer of metal silicide. A layer of insulating material is deposited over the semiconductor device. The via is defined by photolithography on the layer of insulating material, the photolithographic process illuminating selected portions of the semiconductor device with light having a predetermined exposure wavelength to define the via, the antireflection layer formed of a material and having a thickness that reduces reflections at the predetermined wavelength.

### BRIEF DESCRIPTION OF THE DRAWINGS

FIGS. 1-5 illustrate the process steps for forming a salicide structure in accordance with conventional teachings.

FIGS. 6 illustrates an undesirable aspect of the FIG. 5 manufacturing step.

FIGS. 7-12 illustrate stages in the manufacture of MOS devices incorporating salicide structures in accordance with the present invention.

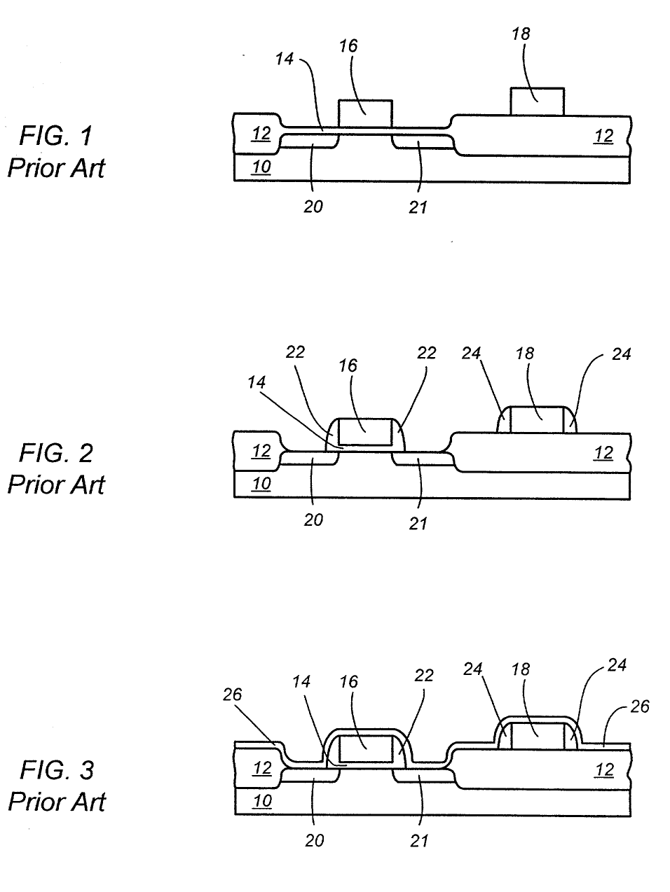

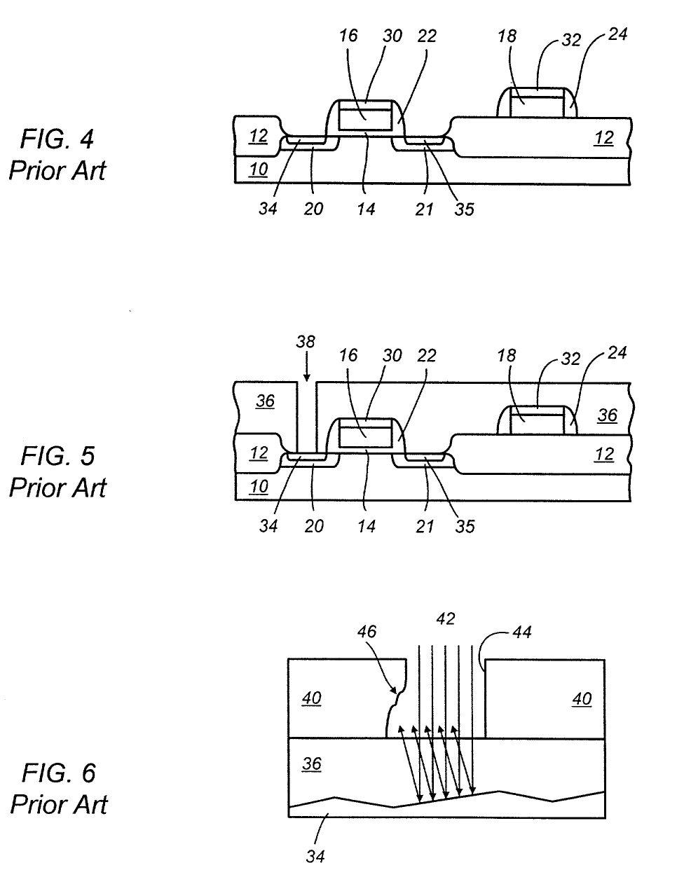

### DETAILED DESCRIPTION OF THE PREFERRED EMBODIMENTS

Preferred embodiments of the invention provide a method of more reliably forming contacts to silicide layers formed on doped silicon regions. A contact region of doped silicon has a layer of metal silicide on its surface and a layer of a conductive material formed over the surface of the metal silicide, with the thickness and material chosen such that the conductive layer functions as an antireflection layer during contact via photolithography. Another aspect of the present invention provides a method of forming an antireflection layer on the surface of a contact region. In accordance with this aspect, a metal layer is deposited on the surface of a doped silicon contact region and an anneal is performed to convert the metal layer at least partially to metal silicide. A subsequent anneal converts the metal silicide region into a lower resistivity phase. A third anneal, preferably conducted as a rapid thermal anneal (RTA) in a nitrogen or ammonia ambient, converts a surface portion of the metal silicide to titanium nitride. In particularly preferred embodiments, the third anneal forms a titanium nitride layer of a thickness appropriate to function as an antireflection layer for the wavelength of light used in the lithography of the contact via. According to these embodiments, the thickness of the titanium nitride layer is made equal to one quarter of the wavelength of the light used to expose the photoresist layer in the formation of the contact via, adjusted to account for the index of refraction of the material used for the titanium nitride layer.

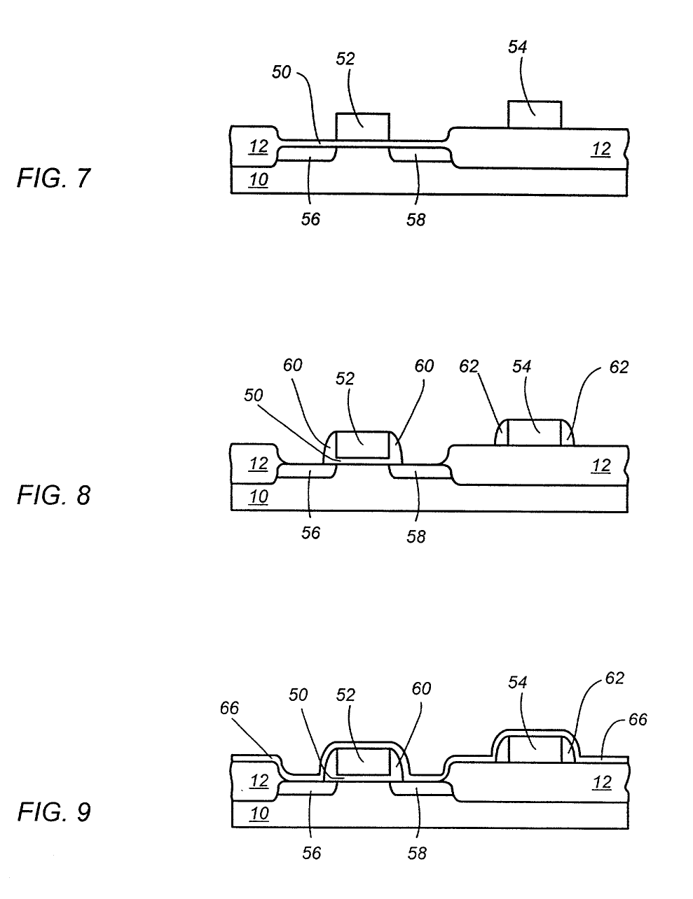

Preferred embodiments of the invention are now described with reference to FIGS. 7-12. While these figures illustrate particularly preferred embodiments of the present invention for making contact to the source/drain regions of MOS transistors in a particular configuration of a semiconductor device, embodiments of the present invention can be used to form contacts to various conductors in a wide variety of semiconductor devices. In addition, while the description of the following embodiments emphasizes the formation of NMOS devices, contacts in accordance with the present invention may be implemented to advantage in PMOS devices as well. This is true whether the polysilicon of the PMOS gate is doped N-type or P-type. Although it is possible to use the salicide structure described herein only for the contacts of a device, whether to the substrate or to electrodes or wiring lines, it is presently believed most desirable to use the described salicide structure for the first level polysilicon lines as well as the substrate contact regions.

FIG. 11 illustrates in cross section a small portion of a semiconductor circuit incorporating a MOS device at an early stage in the manufacturing process. A P-type substrate 10 is provided and device isolation regions such as field oxide regions 12 are provided as necessary. A gate oxide layer 50 is thermally grown in the conventional manner to a thickness of between about 30 to about 200 Å. Polysilicon is deposited by LPCVD to a thickness of 1000-4000 Å and is doped either in situ during deposition by the addition of the appropriate dopant gas during the CVD process or by later ion implantation. The polysilicon layer is patterned using conventional photolithography to form a polysilicon gate electrode 52 and a polysilicon wiring line 54 (FIG. 7). Lightly doped drain implantations are made into the source/drain regions 56, 58 in the well known manner using implantations of arsenic, phosphorus, boron or boron fluoride ions to a dose of between about 5×10¹² ions/cm² to about 2×10¹⁴ ions/cm² at an energy of between about 5 to 80 KeV. Next, a layer of CVD oxide is deposited over the surface of the device and the oxide layer is then etched back to form silicon oxide spacers 60, 62 as shown in FIG. 8.

The heavily doped portions of the source/drain regions 56, 58 are then formed by implantation. Typically, the heavily doped regions are formed by an implantation of arsenic, antimony, phosphorus, boron or boron fluoride ions to a dose of between about 1×10¹⁴ ions/cm² to about 1×10¹⁶ ions/cm² at an energy of between about 5 to 200 KeV. The source/drain regions 56, 58 are then activated by heating the device to a temperature of between about 800° C. to 1100° C. for between 10 seconds (RTA, higher temperature) and 60 minutes (Furnance, lower temperature). Next, the silicide portions of the salicide structures are formed. As is known in the art, acceptable silicide layers can be formed using a number of different base metals, including titanium, cobalt, molybdenum, nickel, platinum and palladium. At the present time, titanium silicide is the most widely implemented, but both cobalt and nickel silicides are believed to have desirable characteristics for reduced line width devices. The processing steps characteristic to each of these different silicides are well known and reported in the literature. Accordingly, while the following description is made in terms of titanium silicide, other silicides can also be utilized in this process, as is known in the art. After thermal activation of the dopants, the native (thermal) oxide formed in this process is removed using a dilute HF solution, and then a thin layer of the metal to be silicided is deposited over the device using physical vapor deposition (e.g., sputtering). In the illustrated embodiment, titanium is deposited to a thickness of between about 200 Å to 800 Å, most preferably about 400 Å, producing a thin metal layer 66 over the surface of the device, as shown in FIG. 9. The thickness of metal to be deposited is determined by balancing the need to deposit sufficient titanium to form a uniform layer with sufficient metal to provide a desirably conductive titanium silicide layer against the need to leave sufficient silicon below the silicided structures. Excessive silicon consumption during silicidation can lead to unacceptable junction leakage from the source/drain regions, among other problems.

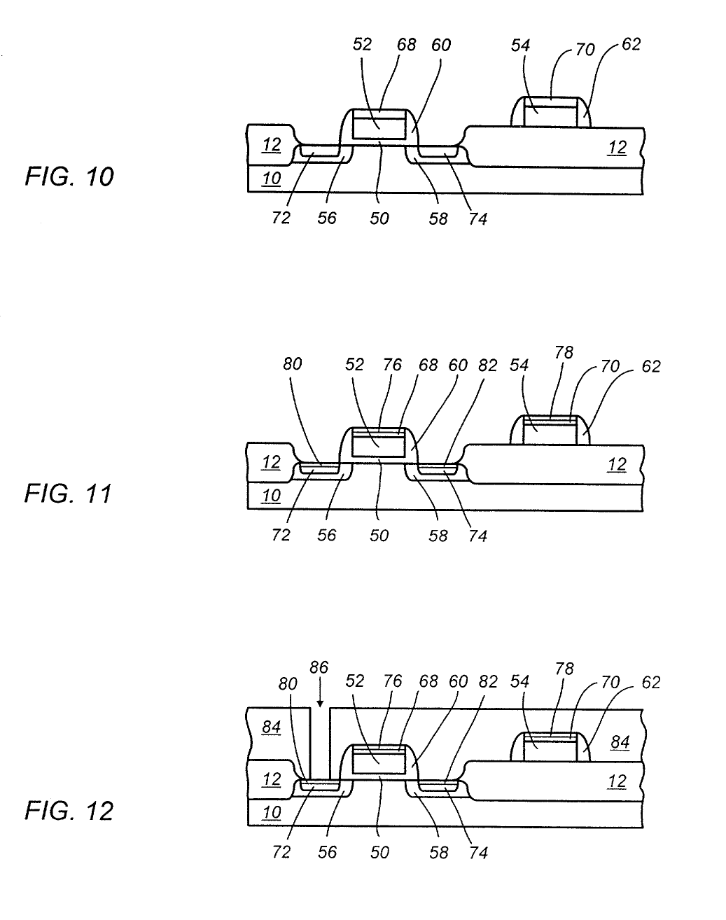

Preferably, the resulting structure is subjected to a first RTA at a temperature within the range of 600-750° C., more preferably of about 730° C., for 10 to 120 seconds, more preferably 20 to 60 seconds, in a nitrogen ambient consisting of a flow of N₂ gas at about 5 slm (standard liters per minute). For cobalt silicide, a temperature of about 550-600° C. is preferably used for the initial silicidation step. Titanium nitride, titanium-rich titanium silicide, titanium oxide and unreacted titanium are then etched from the surface of the device in a solution of NH₄OH, H₂O₂ and H₂O (for example, at a ratio of 1:1:5), leaving titanium silicide layers 72, 74 over the heavily doped portions of the source/drain regions 56, 58, as shown in FIG. 10. Alternately, a solution of H₂SO₄ and H₂O₂ (for example, at a ratio of 1:4) might be used in the etching process. Titanium silicide regions 68, 70 also remain over the polysilicon portion 52 of the gate electrode and over the polysilicon portion 54 of the wiring line. The remaining titanium silicide is then converted to the lower resistivity phase in an RTA at a temperature within a range of about 700° C. to 900° C. for between about 10 to 60 seconds. Most preferably, the second RTA is performed at a temperature of about 850° C. for about 30 seconds, in a nitrogen ambient consisting of a flow of N₂ gas at about 5 slm.

At this point, little or no nitrogen has been incorporated in the titanium silicide layers. It has been observed that RTA processes in nitrogen ambients introduce little or no nitrogen into the titanium silicide layers at temperatures at or below about 850° C. Thus, the surface of the possible contact regions have a surface layer of titanium silicide which, as discussed above, can be highly reflective at the wavelengths used in present and future photolithography processes. A further anneal step is preferably now performed to form an antireflection layer on the surface of the silicide layer. Most preferably, the anneal is performed as a rapid thermal anneal (RTA) process at a temperature within the range of 800-900° C., more preferably of about 900° C., for 10 to about 60 seconds, more preferably about 30 seconds, in a nitrogen ambient consisting of a flow of N₂ or NH₃ gas at about 10 slm. As shown in FIG. 11, this third RTA process forms titanium nitride layers 76, 78, 80 and 82 on titanium silicide layers 68, 70, 72 and 74, respectively. It is preferred that the various titanium silicide layers 68, 70, 72 and 74 not be completely consumed in this process. The thickness of the particular titanium nitride layers formed is controlled both by the temperature of the RTA process (higher temperatures, thicker TiN) and by the duration of the RTA process (longer RTA, thicker TiN). Since it is simple to measure the thickness of titanium nitride layers using ellipsometry or other thin film measurement techniques, optimization of the process parameters necessary to achieve a desired thickness for the titanium nitride layer which optimizes the level of distortion of the contact via that occurs during photolithography.

In the discussed embodiments, a titanium nitride layer is formed over the titanium silicide layer. It is possible to utilize other metal silicides in a salicide structure, however, and possible to form satisfactory antireflection layers from those materials. In particularly preferred embodiments of the present invention, the material and thickness of the conductive surface layers 76, 78, 80, and 82 are chosen so that the layers function as an antireflection coating to reduce reflections from the surface of the silicide layers in the photolithography steps used to define contact vias 86 through the oxide layer 84 (FIG. 12). Of course, it is possible that contact vias will not be formed to all of these layers. Accordingly, it is possible to not form antireflection coatings on all of these layers. Preferably, however, for those silicide regions to which contact vias are formed, a conductive surface layer is provided on the silicide regions which functions as a quarter wave plate at the wavelength of light used to expose the photoresist layer in the contact via photolithography process. Depending on the index of refraction of the material, the thickness required for different materials to function as quarter wave plates varies for a given wavelength of light. Thus, for i-line radiation (λ=3650 Å) a preferred thickness for a titanium nitride layer is about 300 Å. It should be appreciated that these layers will have significant levels of antireflection properties for small variations from the preferred thicknesses, however. As a practical matter, this is important to the effectiveness of the present invention because the processing used to first form the silicide layer and then to form the antireflection layer, along with the roughness of the silicide surface, introduce variations in the thickness of the antireflection layer. Additionally, it is to be expected that the surface layer will not be uniformly titanium nitride, since there is a possibility that other materials such as silicon oxide might be left as inclusions within the titanium nitride layer. Such inclusions will also affect the antireflection properties of the surface layer.

Subsequent processing proceeds in the conventional manner, with the deposition of a interpolysilicon or pre-metal dielectric layer 84 such as atmospheric pressure CVD SiO₂ or borophosphosilicate glass (BPSG) over the FIG. 11 structure. Vias 86 are formed through the CVD SiO₂ or BPSG down to contact regions 80 as necessary, forming polysilicon or metal contacts and first metal or second polysilicon wiring lines and interconnects. Often, aluminum, aluminum-silicon or aluminum-copper alloys are used to fill vias 86. Alternately, refractory metals including tungsten might be used to fill vias 86, forming vertical interconnects. The remaining structures and processes are conventional and so are not described further herein.

The present invention has been described in terms of certain preferred embodiments. The invention is not, however, limited to the specific embodiments described, but also includes such modifications and variations as fall within the scope of the following claims.

What is claimed:

1. A method of making a semiconductor device, comprising the steps of:
providing a semiconductor substrate and doping a contact region to render the contact region conductive;
depositing a layer of metal over the semiconductor device and on the contact region;
performing a first anneal of the semiconductor device to produce a layer of metal silicide on the contact region;
removing unreacted portions of the layer of metal from the semiconductor device;
rapid thermal annealing the semiconductor device in a nitrogen ambient at a temperature sufficient to cause the nitrogen ambient to react with the layer of metal silicide on the contact region, causing a layer of metal nitride to grow on the layer of metal silicide;
providing a layer of insulating material over the semiconductor device; and
photolithographically defining a via through the layer of insulating material to expose the layer of metal nitride.

2. The method of claim 1, wherein the contact region is a source/drain region of a MOS transistor.

3. The method of claim 1, wherein the first anneal entirely consumes the metal layer above the contact region.

4. The method of claim 1, wherein the first anneal is performed at a temperature of less than 750° C. for less than 100 seconds.

5. The method of claim 4, wherein the layer of metal is titanium and the first anneal is followed by a second anneal at a temperature of at least 800° C. for a time between about 10 to 30 seconds.

6. The method of claim 5, wherein the step of rapid thermal annealing is performed at a temperature of at about 900° C.

7. The method of claim 5, wherein the step of removing unreacted portions comprises etching the semiconductor device in a solution of NH₄OH, H₂O₂ and H₂O.

8. The method of claim 1, wherein the metal is selected from the group consisting of titanium, cobalt, and nickel.

9. The method of claim 1, wherein the step of photolithographically defining includes illuminating selected portions of the semiconductor device with light having a predetermined exposure wavelength, and wherein the layer of metal nitride reduces reflections from a surface of the layer of metal silicide at the predetermined exposure wavelength.

10. The method of claim 9, wherein the layer of metal nitride acts as a quarter wave plate at the predetermined exposure wavelength.

11. A method of making a semiconductor device, comprising the steps of:
providing a semiconductor substrate and doping a contact region to render the contact region conductive;
depositing a layer of metal over the semiconductor device and on the contact region;
performing a first anneal of the semiconductor device to produce a layer of metal silicide on the contact region;
removing unreacted portions of the layer of metal from the semiconductor device;
rapid thermal annealing the semiconductor device in an annealing ambient to form a conductive antireflection layer on the layer of metal silicide;
providing a layer of insulating material over the semiconductor device; and
photolithographically defining a via through the layer of insulating material, the photolithographic process illuminating selected portions of the semiconductor device with light having a predetermined exposure wavelength to define the via, the antireflection layer formed of a material and having a thickness that reduces reflections at the predetermined wavelength.

12. The method of claim 11, wherein the metal is selected from the group consisting of titanium, cobalt, nickel, platinum and palladium.

13. The method of claim 11, wherein the thickness of the antireflection layer is determined by varying duration and temperature of the rapid thermal annealing step to reduce reflections from a surface of the metal silicide layer.

14. The method of claim 11, wherein the step of rapid thermal annealing is performed in a nitrogen ambient and the antireflection layer is a metal nitride.
